(19) United States
(12) Patent Application Publication
(10) Pub. No.: US 2026/0096273 A1
(43) Pub. Date: Apr. 2, 2026

(54) LIGHT EMITTING DEVICE AND DISPLAY DEVICE INCLUDING THE SAME

(71) Applicant: SEOUL SEMICONDUCTOR CO., LTD., Ansan-si (KR)

(72) Inventors: Sang Min SHIN, Ansan-si (KR); Seung Sin JANG, Ansan-si (KR)

(73) Assignee: SEOUL SEMICONDUCTOR CO., LTD., Ansan-si (KR)

(21) Appl. No.: 19/338,383

(22) Filed: Sep. 24, 2025

Related U.S. Application Data
(60) Provisional application No. 63/701,349, filed on Sep. 30, 2024.

(51) Int. Cl. H10H 29/855

(52) U.S. Cl. CPC H10H 29/855

(57) ABSTRACT

A light emitting device is provided including: a plurality of light emitters to generate light; and a plurality of refractors disposed on top surfaces of at least some of the light emitters. A curvature of one of the plurality of refractors may be different from a curvature of another one of the plurality of refractors.

### CROSS-REFERENCE TO RELATED APPLICATIONS

The present application is related to and claims the benefit of priority from U.S. Provisional Application No. 63/701,349, filed on Sep. 30, 2024, the entire contents of which are incorporated herein by reference.

### TECHNICAL FIELD

Various implementations of the disclosed technology relate to a light emitting device and a display device including the same.

### BACKGROUND

Recently, light emitting diodes (LEDs) have been widely used. LEDs convert electrical signals into light such as infrared, visible light, and ultraviolet light by utilizing the characteristics of compound semiconductors.

As the luminous efficiency of light emitting diodes increases, light emitters are being applied to various fields including display devices, lighting equipment, and automotive lamps.

Light is produced by the combination of the three primary colors of red, green, and blue (RGB), and various colors can be realized by combining the three primary colors of RGB. In display devices that combine red (R), green (G), and blue (B) light, there is a growing need for technological advancements that can provide clearer images and enhance color reproduction.

### SUMMARY

Embodiments of the disclosed technology may provide a light emitting device capable of efficiently refracting light, and a display device including the same.

Embodiments of the disclosed technology may provide a light emitting device having a stable structure without damage such as cracks, even under heat generation or thermal stress, and a display device including the same.

Embodiments of the disclosed technology may provide a light emitting device with improved contrast by minimizing optical interference between light emitters, and a display device including the same.

Embodiments of the disclosed technology may provide a light emitting device with improved brightness by controlling the direction of refraction, and a display device including the same.

Embodiments of the disclosed technology can provide a light emitting device for a display capable of improving color brightness and color reproduction.

In an aspect, a light emitting device according to one embodiment includes: a plurality of light emitters; and a plurality of refractors disposed on top surfaces of at least one of the light emitters, wherein a curvature of one of the plurality of refractors is different from a curvature of another one of the plurality of refractors.

Further, there may be provided the light emitting device further including: an optical component on which the plurality of refractors are arranged and which covers the plurality of light emitters to allow light generated from the plurality of light emitters to pass therethrough.

Further, there may be provided the light emitting device in which the plurality of light emitters include: a first light emitter configured to generate a first light having a first peak wavelength; and a second light emitter configured to generate a second light having a second peak wavelength different from the first peak wavelength of the first light emitter, and wherein the plurality of refractors include: a first refractor disposed above the first light emitter and formed to be convex upward and configured to collect light from the first light emitter; and a second refractor disposed above the second light emitter and formed to be convex upward and configured to collect light from the second light emitter.

Further, there may be provided the light emitting device in which a radius of curvature of the first refractor is smaller than a radius of curvature of the second refractor.

Further, there may be provided the light emitting device in which a center of the radius of curvature of the first refractor is disposed on a center region of the radius of curvature of the second refractor.

Further, there may be provided the light emitting device in which the plurality of light emitters further include: a third light emitter configured to emit a third light having a third peak wavelength different from those of the first peak wavelength and the second peak wavelength, and the plurality of refractors are not disposed in a region directly above the third light emitter.

Further, there may be provided the light emitting device in which the plurality of light emitters further include a third light emitter configured to emit light of a different color from those of the first light emitter and the second light emitter, and the plurality of refractors further include a third refractor disposed above the third light emitter and formed to be convex upward and configured to collect light from the third light emitter.

Further, there may be provided the light emitting device in which a radius of curvature of the third refractor is greater than a radius of curvature of the first refractor and a radius of curvature of the second refractor, and the radius of curvature of the second refractor is greater than the radius of curvature of the first refractor.

Further, there may be provided the light emitting device in which a center of the radius of curvature of the third refractor is located below a center of the radius of curvature of the first refractor and a center of the radius of curvature of the second refractor, and the center of the radius of curvature of the second refractor is disposed below the center of the radius of curvature of the first refractor.

Further, there may be provided the light emitting device in which a radius of curvature of the first refractor and a radius of curvature of the second refractor are the same, and a radius of curvature of the third refractor is greater than the radius of curvature of the first refractor and the radius of curvature of the second refractor.

Further, there may be provided the light emitting device in which a center of the radius of curvature of the third refractor is disposed below a center of the radius of curvature of the first refractor and a center of the radius of curvature of the second refractor.

Further, there may be provided the light emitting device in which a height of the third refractor is smaller than a height of the first refractor and a height of the second refractor.

In an aspect, the light emitting device according to an embodiment includes: a first spacer disposed between the first refractor and the first light emitter and configured to transmit light from the first light emitter, and a second spacer disposed between the second refractor and the second light emitter, and configured to transmit light of the second light emitter, wherein the center of the radius of curvature of the first refractor is disposed above the first spacer, and the center of the radius of curvature of the second refractor is disposed above the second spacer.

Further, there may be provided the light emitting device in which the first refractor, the second refractor, and the third refractor are arranged to be spaced from each other in a horizontal direction, and a separation distance between the first refractor and the second refractor is the same as a separation distance between the second refractor and the third refractor.

Further, there may be provided the light emitting device in which a center of the radius of curvature of the third refractor is disposed at the same level as or above a center of the radius of curvature of the first refractor and a center of the radius of curvature of the second refractor. Further, there may be provided the light emitting device in which a height of the third refractor is equal to or greater than a height of the first refractor and a height of the second refractor.

Further, there may be provided the light emitting device in which the first refractor, the second refractor, and the third refractor are arranged to be spaced from each other in a horizontal direction, and a separation distance between the first refractor and the second refractor is greater than a separation distance between the second refractor and the third refractor.

In an aspect, a light emitting device according to an embodiment includes: a light blocker configured to block light generated from the plurality of light emitters, wherein the light blocker may be disposed between the plurality of light emitters and on an outer side of the plurality of light emitters.

In an aspect, a light emitting device according to an embodiment includes: a plurality of light emitters configured to emit light; a plurality of lower refractors arranged above the plurality of light emitters and configured to collect light generated from at least one of the plurality of light emitters; and a plurality of upper refractors arranged above the plurality of lower refractors to collect light transmitted through the plurality of lower refractors, wherein a curvature of one of the plurality of lower refractors and the plurality of upper refractors is different from a curvature of another one of the plurality of lower refractors and the plurality of upper refractors.

In an aspect, a display device according to an embodiment includes: a light emitting device; and a circuit board on which the light emitting device is arranged, wherein the light emitting device includes: a plurality of light emitters; and a plurality of refractors configured to collect light generated from at least one of the light emitters, and wherein a curvature of one of the plurality of refractors is different from a curvature of another of the plurality of refractors.

The light emitting device of the display device according to one embodiment of the disclosed technology may efficiently refract light, thereby preventing optical interference.

According to the embodiments of the disclosed technology, the light emitting device may have a stable structure without damage such as cracks even under heat generation or thermal stress.

According to the embodiments of the disclosed technology, it is possible to improve contrast by minimizing the optical interference between the light emitters.

According to the embodiments of the disclosed technology, it is possible to improve brightness by adjusting the direction of refraction.

According to the embodiments of the disclosed technology, the extraction efficiency may be increased, which results in high illuminance.

According to the embodiments of the disclosed technology, color brightness and color reproduction may be improved.

### BRIEF DESCRIPTION OF DRAWINGS

FIG. 1 is an exploded perspective view of a display device according to an embodiment of the disclosed technology.

FIG. 2 is a cross-sectional view of the display device shown in FIG. 1.

FIG. 3 is an exploded perspective view of a light emitting device of the display device according an embodiment of the disclosed technology.

FIG. 4 is a drawing showing a plurality of light emitters and a plurality of refractors of the light emitting device according to an embodiment of the disclosed technology.

FIG. 5 is a drawing showing a light emitting device according to an embodiment of the disclosed technology, wherein a plurality of refractors are not arranged in a region directly above a third light emitter.

FIG. 6 is a drawing showing a plurality of light emitters and a plurality of refractors of a light emitting device according to an embodiment of the disclosed technology.

FIG. 7 is a drawing showing a plurality of light emitters and a plurality of refractors of a light emitting device according to an embodiment of the disclosed technology.

FIG. 8 is a drawing showing a spacer of a light emitting device according to an embodiment of the disclosed technology.

FIG. 9 shows a first example of a plurality of refractors and a light blocker of a light emitting device according to an embodiment of the disclosed technology.

FIG. 10 shows a second example of the plurality of refractors and the light blocker of the light emitting device according to an embodiment of the disclosed technology.

FIG. 11 shows a third example of the plurality of refractors and the light blocker of the light emitting device according to an embodiment of the disclosed technology.

FIG. 12 is a drawing showing an auxiliary refractor of a light emitting device according to an embodiment of the disclosed technology.

FIG. 13 is a drawing showing a plurality of lower refractors and a plurality of upper refractors of a light emitting device according to an embodiment of the disclosed technology.

FIG. 14 is a drawing showing a light emitting device according to an embodiment of the disclosed technology.

FIG. 15 is a drawing showing a top view of the light emitting device of FIG. 14.

FIG. 16 is a drawing showing an enlarged view of a refractor of the light emitting device of FIG. 14.

### DETAILED DESCRIPTION

In the following description, for the purposes of explanation, numerous specific details are set forth in order to provide thorough understanding of various exemplary embodiments or implementations of the disclosed technology. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device 10 according to an embodiment of the disclosed technology and a display device 1 including the same will be described.

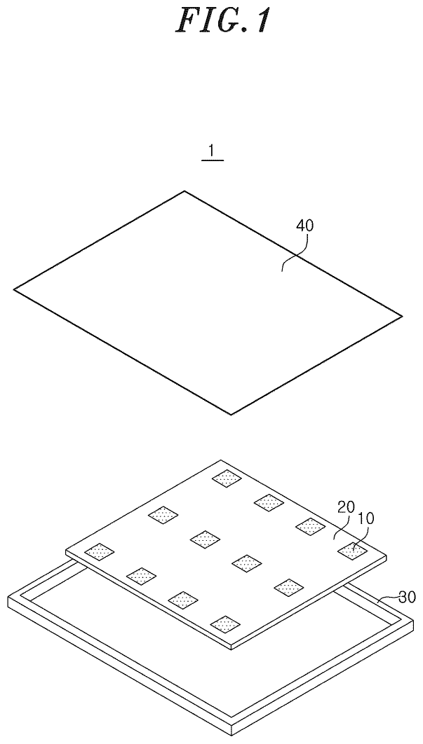

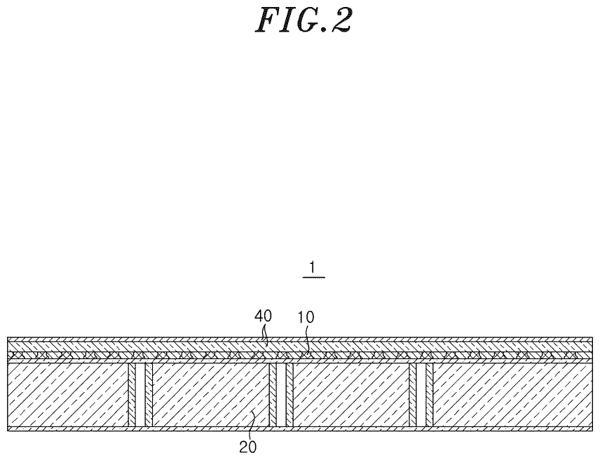

Referring to FIGS. 1 and 2, the display device 1 according to an embodiment of the disclosed technology is capable of displaying characters, symbols, images, or videos. Further, the display device 1 may be mounted on a vehicle. Such a display device 1 may be included in a taillight, a headlight, a rear lamp, a tail lamp, etc. Furthermore, the display device 1 mounted on a vehicle can emit red light, yellow light, or white light to display information such as a stop signal or characters to the outside. In addition, the display device 1 may reduce optical interference between a plurality of light emitting devices 10 to minimize interference between operating areas, thereby implementing a high-quality display device with a distinct contrast ratio and a distinct contrast. The display device 1 may include a light emitting device 10, a circuit board 20, a cover 30, and an optical sheet 40.

The cover 30 may have a structure with an open top surface and may accommodate the light emitting device 10, the circuit board 20, and the optical sheet 40 therein. The cover 30 may include a metal material and may protect the internal components from external environments.

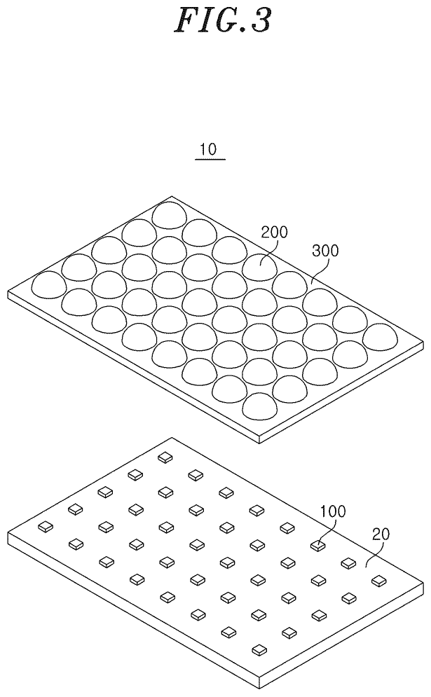

A light emitting module may include the circuit board 20 and at least one light emitting device 10. The light emitting module of the present embodiment may have the same characteristics as the light emitting device 10 to be described later with reference to FIGS. 3 to 15. The light emitting module of the display device 1 according to one embodiment may be composed of the light emitting devices described in FIGS. 3 to 15, or various combinations of their components.

The optical sheet 40 may include at least one of a diffusion sheet, a condensing sheet, and a protective sheet. The optical sheets 40 may include one or more of each of a diffusion sheet, a condensing sheet, and a protective sheet, or may include at least one of the diffusion sheet, the condensing sheet, and the protective sheet in one or more quantities. For example, the optical sheet 40 may consist of one diffusion sheet and two condensing sheets, or two diffusion sheets and one condensing sheet. The optical sheet 40 may be disposed parallel to the circuit board 20, thereby enabling the implementation of an efficient planar light source.

Referring further to FIG. 3, the light emitting device 10 can generate light. The light emitting device 10 may be provided as a plurality of light emitting devices arranged in at least one region on the circuit board 20. In addition, the plurality of light emitting devices 10 may be electrically connected to an electrical circuit arranged on the circuit board 20. The electrical circuit may be formed in a multilayer structure and may be formed with different thicknesses for each region as needed. The plurality of light emitting devices 10 may be arranged adjacent to each other and may each generate light. For example, the plurality of light emitting devices 10 may be arranged in N rows and M columns and may each generate light. In other words, the plurality of light emitting devices 10 may be arranged in an N×M matrix and may each generate light. The number of rows, N, and the number of columns, M, of the plurality of light emitting devices 10 may be the same or different. The number of rows, N, may be smaller than the number of columns, M. The number of rows N may be 1.2 to 1.8 times greater than the number of columns M. This configuration may reduce light deviation between the long and short axes of the display device 1. The plurality of light emitting devices 10 arranged in an N×M matrix may be proportional to the scaling factor of the display device 1. In addition, each light emitting device 10 may be individually driven for each region to control brightness or the light emitting area. The light emitting device 10 may include a light emitter 100, a refractor 200, and an optical component 300. The refractor 200 may be arranged in an N×M matrix corresponding to the regions of the light emitters 100 to control lights generated from the respective light emitters 100. Each of the plurality of light emitting devices 10 may form a pixel or a sub-pixel.

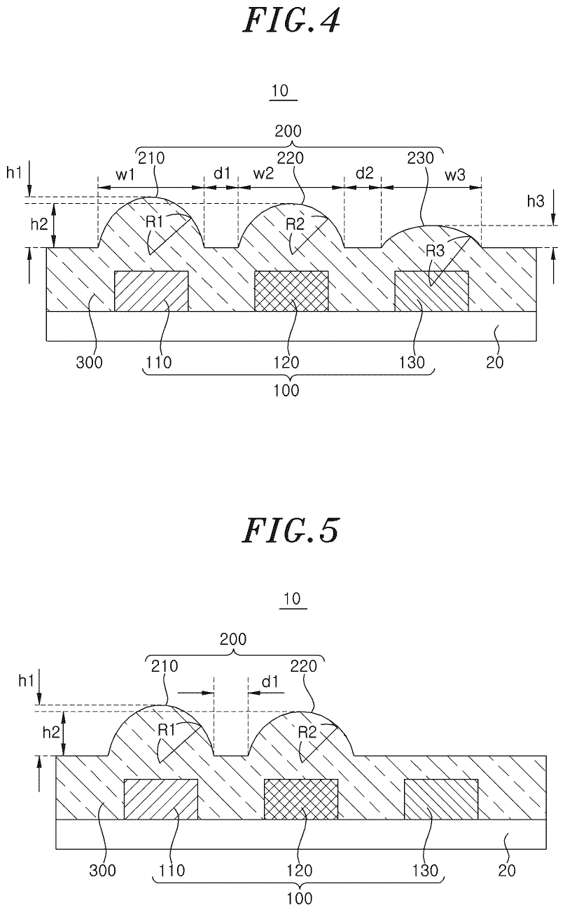

Referring further to FIG. 4, the light emitter 100 can generate light. The overall thickness of the light emitter 100 may be in the range of 5 μm to 200 μm. At least two adjacent light emitters 100 may have different thicknesses. In this case, the thickness difference may be in the range of 10% to 20%. This may allow for adjustment of the refraction direction between adjacent light emitters 100, thereby minimizing the luminance interference. In addition, the light emitter 100 may include one or more of aluminum gallium arsenide (AlGaAs), gallium arsenide phosphide (GaAsP), aluminum gallium indium phosphide (AlGaInP), gallium phosphide (GaP), indium gallium nitride (InGaN), aluminum gallium phosphide (AlGaP), and zinc selenide (ZnSe). The light emitter 100 may include a first conductive semiconductor layer, a second conductive semiconductor layer, and an active layer.

The first conductive semiconductor layer may be electrically connected to a 1-1 thermal conductor, which will be described later. The first conductive semiconductor layer may include an n-type impurity (e.g., Si, Ge, Sn), in which case the first conductive semiconductor layer may be an n-type semiconductor layer. However, this is merely an example, and the first conductive semiconductor layer may also include a p-type impurity.

The active layer may be laminated on the first conductive semiconductor layer. For example, the active layer may be positioned between the first conductive semiconductor layer and the second conductive semiconductor layer.

The second conductive semiconductor layer may be laminated on the active layer and may be electrically connected to a 1-2 thermal conductor. The second conductive semiconductor layer may include a p-type impurity (e.g., Mg, Sr, Ba), in which case the second conductive semiconductor layer may be a p-type semiconductor layer. However, this is merely an example, and the second conductive semiconductor layer may also include an n-type impurity.

The light emitter 100 is electrically connected to the electrical circuit of the circuit board 20 and can receive electricity from the outside through the electrical circuit to generate light. The width of the light emitter 100 may be less than or equal to the width of the bottom of the refractor 200, so that light generated from the light emitter 100 may be sufficiently incident on the refractor 200 to increase light extraction efficiency. In this case, the width of the bottom of the refractor 200 may be at least 1.1 times greater than the width of the light emitter 100. The height of the light emitter 100 may be smaller than the height of the optical component 300. The height of the optical component 300 may be at least 1.1 times greater than the height of the light emitter 100, ensuring a sufficient refraction path length of the light for adjusting the angle of emitted light. In addition, the light emitter 100 may be provided as a plurality of light emitters. The plurality of light emitters 100 may be arranged to be spaced apart from each other along an upper surface of the circuit board 20, and accordingly, the refractors 200 may also be arranged to be spaced apart from each other. In this case, the spacing between the light emitters 100 may be greater than the spacing between the refractors 200. This reduces the optical interference between the spaced light emitters 100. Further, the difference between the spacing of the light emitters 100 and that of the refractors 200 may be within a range of 2% to 20%. If the difference in separation distance exceeds this range, the optical uniformity of the light emitting device may deteriorate, while if it is smaller than this range, the optical interference may occur.

The plurality of light emitters 100 may have different beam angles. The plurality of light emitters 100 may include a first light emitter 110, a second light emitter 120, and a third light emitter 130.

The first light emitter 110, the second light emitter 120, and the third light emitter 130 may have similar wavelengths. In this case, the difference in peak wavelengths among the first light emitter 110 to the third light emitter 130 may be less than 2 nm. This may enhance color purity. Additionally, the difference in full width at half maximum (FWHM) based on the peak wavelengths of the first to third light emitters 130 may be less than 5 nm. This may reduce differences in visual sensitivity, thereby improving display quality.

In addition, the first light emitter 110, the second light emitter 120, and the third light emitter 130 may generate light having different peak wavelengths. For example, the first light emitter 110 may generate blue light having a peak wavelength in the range of 400 nm to 490 nm, the second light emitter 120 may generate green light having a peak wavelength in the range of 490 nm to 570 nm, and the third light emitter 130 may generate red light having a peak wavelength in the range of 600 nm to 750 nm. Through the first light emitter 110, the second light emitter 120, and the third light emitter 130, the light emitting device 10 may generate not only blue, green, and red light, but also white light.

When the first light emitter 110, the second light emitter 120, and the third light emitter 130 are arranged in sequence, the difference between the peak wavelengths of adjacent first and second light emitters 110 and 120 may be greater than the difference between the peak wavelengths of adjacent second and third light emitters 120 and 130. The difference between the peak wavelengths of the first and second light emitters 110 and 120 may range from 90 nm to 120 nm. The difference between the peak wavelengths of the second and third light emitters 120 and 130 may range from 40 nm to 65 nm. The difference between the peak wavelengths of the first and second light emitters 110 and 120 may be 1.5 to 2.5 times greater than that between the second and third light emitters 120 and 130. This may improve color distinction for each color and enhance color purity and color reproduction.

In addition, the first light emitter 110, the second light emitter 120, and the third light emitter 130 may have dominant wavelengths different from their peak wavelengths. This allows for improved optical output by securing a more luminous flux, even when perceived as the same color. The difference between the peak wavelength and the dominant wavelength may vary for each light emitter.

The peak wavelength of the first light emitter 110 may be longer than its dominant wavelength. For example, the peak wavelength of the first light emitter 110 may be 5 nm to 10 nm longer than its dominant wavelength. This enhances the visual perception while securing the luminous intensity. Further, the peak wavelength of the second light emitter 120 may be shorter than its dominant wavelength, for example, by 5 nm to 10 nm. This similarly improves the visual perception and the luminous intensity.

Similarly, the peak wavelength of the third light emitter 130 may be shorter than its dominant wavelength. For instance, the peak wavelength of the third light emitter 130 may be 1 nm to 8 nm shorter than the dominant wavelength. This improves the visual perception while maintaining the luminous intensity.

The difference between the peak wavelength and the dominant wavelength of the third light emitter 130 may be smaller than that of the first light emitter 110. Alternatively, the difference between the peak wavelength and the dominant wavelength of the third light emitter 130 may be smaller than that of the second light emitter 120. This may compensate for differences in visual sensitivity to relatively low-sensitivity short-wavelength light, thereby improving the color reproducibility.

Furthermore, the separation distances between the first, second, and third light emitters 110, 120, and 130 may differ. The separation distance between the first and second light emitters 110 and 120 and the separation distance between the second and third light emitters 120 and 130 may differ. This may enhance optical uniformity among the emitters.

The refractor 200 can collect light generated from the light emitter 100. The refractor 200 may be disposed above the light emitter 100. The refractor 200 may have an upwardly convex shape, but is not limited thereto, and may also have a concave shape. The refractor 200 may enhance the brightness of light generated from the light emitter 100. The beam angle of light passing through the refractor 200 may be smaller than the beam angle of light generated from the light emitter 100. For example, the refractor 200 may narrow the beam angle of light generated from the light emitter 100 to ⅘ or less and emit it to the outside. The difference in beam angles between the light generated from the light emitter 100 and the light emitted through the refractor 200 may be 20 degrees or more. The refractor 200 may be formed integrally with the optical component 300, and in such a case, there is no interface, so that light absorption at the interface is reduced, thereby improving the light extraction efficiency.

In addition, the refractor 200 and the optical component 300 may be formed of materials having the same refractive index, which reduces the total internal reflection of the beam angle due to the difference in the refractive index. For example, the refractor 200 may be formed of silicon together with the optical component 300, but is not limited thereto, and may be formed of various light-transmitting materials such as epoxy, glass, and sapphire. The bottom width of the refractor 200 may be formed to be larger than the width of the light emitter 100. The height of the refractor 200 may be greater than the height of the light emitter 100. In addition, the edge of the refractor 200 may be rounded to have a curved shape in at least one region, which helps reduce edge-concentrated stress and lowers the risk of physical damage to the refractor 200. The curvature of the rounded edge of the refractor 200 may be greater than the radius of curvature at the center of the refractor 200. This may effectively reduce edge-concentrated stress.

The refractor 200 may be provided as a plurality of refractors arranged in the direction in which the plurality of light emitters 100 are arranged. The plurality of refractors 200 may be spaced apart from each other by an equal distance, but are not limited thereto. For example, the separation distance between some of the plurality of refractors 200 may differ from the separation distance between others of the plurality of refractors 200. This may allow the light profiles of different light emitters 100 to be adjusted to be similar. In addition, the plurality of refractors 200 may be respectively arranged above the plurality of light emitters 100 to collect light generated from at least some of the plurality of light emitters 100. Through the plurality of refractors 200, the light generated from the plurality of light emitters 100 may be efficiently emitted to the outside without undergoing total internal reflection. The plurality of refractors 200 may include a first refractor 210, a second refractor 220, and a third refractor 230.

The first refractor 210 may be disposed above the first light emitter 110 and formed to be convex in one direction to collect light from the first light emitter 110. The light from the first light emitter 110 may be collected. When projected toward the first refractor 210, the first light emitter 110 may be positioned inside the first refractor 210. In addition, the first refractor 210 may be disposed on top of the optical component 300. Through the first refractor 210, the beam angle of the first light emitter 110 may be reduced. For example, the beam angle of the first light emitter 110 in a state without the first refractor 210 and the beam angle of the first light emitter 110 formed by the first refractor 210 may differ by a first angle. The first angle may be greater than a second angle and a third angle, which will be described later.

Further, when the beam angle of the first light emitter 110 is larger than the beam angle of the second light emitter 120 or the third light emitter 130, a radius of curvature R1 of the first refractor 210 may be smaller than a radius of curvature R2 of the second refractor 220 and a radius of curvature R3 of the third refractor 230. Through this configuration, the beam angle of the first light emitter 110 having a wide beam angle may be adjusted to be similar to the beam angles of the second emitter 120 and the third light emitter 130. As a result, luminance uniformity may be improved, thereby enhancing the overall quality of the light emitting device.

Furthermore, the center of the radius of curvature R1 of the first refractor 210 may be disposed above the center of the radius of curvature R2 of the second refractor 220 or the center of the radius of curvature R3 of the third refractor 230, thereby securing a sufficient light refraction path to enhance luminance uniformity and improve the quality of the light emitting device.

In addition, a width w1 of the bottom surface of the first refractor 210 may be formed smaller than a width w2 of the bottom surface of the second refractor 220 or a width w3 of the bottom surface of the third refractor 230. This reduces the amount of light emitted sideways, thereby enhancing luminance uniformity and improving the quality of the light-emitting device. A height h1 of the first refractor 210 may be greater than a height h2 of the second refractor 220 or a height h3 of the third refractor 230, which secures a sufficient light refraction path to enhance the luminance uniformity and improve the quality of the light emitting device.

The second refractor 220 may be disposed above the second light emitter 120 and formed to be convex in one direction to collect light from the second light emitter 120. When projected toward the second refractor 220, the second light emitter 120 may be positioned inside the second refractor 220. In addition, the second refractor 220 may be disposed on top of the optical component 300. Through the second refractor 220, the beam angle of the second light emitter 120 may be reduced. For example, the beam angle of the second light emitter 120 in a state without the second refractor 220 and the beam angle of the second light emitter 120 formed by the second refractor 220 may differ by the second angle. The second angle may be greater than the third angle.

Further, when the beam angle of the second light emitter 120 is smaller than the beam angle of the first light emitter 110 or larger than the beam angle of the third light emitter 130, the radius of curvature R2 of the second refractor 220 may be larger than the radius of curvature R1 of the first refractor 210 and smaller than the radius of curvature R3 of the third refractor 230, which allows the beam emission angles of the first light emitter 110, the second light emitter 120, and the third light emitter 130 to be adjusted to be the same. Furthermore, the center of the radius of curvature R2 of the second refractor 220 may be disposed below the center of the radius of curvature R1 of the first refractor 210 and above the center of the radius of curvature R3 of the third refractor 230. This optimizes the light travel path and enhances the luminance uniformity, thereby improving the quality of the light emitting device. In addition, the width w2 of the bottom surface of the second refractor 220 may be larger than the width w1 of the bottom surface of the first refractor 210 and smaller than the width w3 of the bottom surface of the third refractor 230, which enables adjustment of the travel path of the side-emitted light of the second light emitter 120 to control the emission angle. The height h2 of the second refractor 220 may be smaller than the height h1 of the first refractor 210 and larger than the height h3 of the third refractor 230, which secures the light travel path to optimize the emission angle.

The third refractor 230 may be disposed above the third light emitter 130 and formed to be convex in one direction to collect light from the third light emitter 130. When projected toward the third refractor 230, the third light emitter 130 may be positioned inside the third refractor 230. In addition, the third refractor 230 may be disposed on top of the optical component 300. Through the third refractor 230, the beam angle of the third light emitter 130 may be reduced. For example, the beam angle of the third light emitter 130 in a state without the third refractor 230 and the beam angle of the third light emitter 130 formed by the third refractor 230 may differ by the third angle. The third angle may be smaller than the first angle and the second angle.

Further, when the beam angle of the third light emitter 130 is smaller than the beam angle of the first light emitter 110 or the second light emitter 120, the radius of curvature R3 of the third refractor 220 may be larger than the radius of curvature R1 of the first refractor 210 and the radius of curvature R2 of the second refractor 220. Furthermore, the center of the radius of curvature R3 of the third refractor 230 may be disposed below the center of the radius of curvature R1 of the first refractor 210 and the center of the radius of curvature R2 of the second refractor 220. For example, the width w3 of the bottom surface of the third refractor 220 may be larger than the width w1 of the bottom surface of the first refractor 210 and the width w2 of the bottom surface of the second refractor 220. The height h3 of the third refractor 220 may be smaller than the height h1 of the first refractor 210 and the height h2 of the second refractor 220, which allows adjustment of the refraction distance of light to control the emitted light. This enhances luminance uniformity and improves the quality of the light emitting device.

In addition, a separation distance d1 between the first refractor 210 and the second refractor 220 may be formed to be approximately equal to a separation distance d2 between the second refractor 220 and the second refractor 220, thereby enabling the implementation of a light emitting device with uniform pixel spacing when viewed from the top. In this case, the difference between the separation distance d1 and the separation distance d2 may be less than 10%.

The optical component 300 may be a molding formed to allow light generated from the plurality of light emitters 100 to pass therethrough and cover the plurality of light emitters 100. In addition, the optical component 300 may have the plurality of refractors 200 arranged on one surface. The optical component 300 may be formed integrally with the plurality of refractors 200. For example, the optical component 300 may be formed of the same material as the plurality of refractors 200. Therefore, it is possible to prevent the plurality of refractors 200 and the optical component 300 from being separated due to heat generated from the light emitters 100. However, the disclosed technology is not necessarily limited to the above, and depending on the light profile to be implemented, the plurality of refractors 200 and the optical component 300 may be formed of different materials, and may be formed of materials with different refractive indices for adjusting the angle of refraction. For example, the refractor 200 may be made of a different material from that of the optical component 300 so that its refractive index is higher than that of the optical component 300. This may reduce the design complexity.

In addition, the optical component 300 may be provided as a plurality of optical components spaced apart from each other. The height of the optical component 300 may be greater than the height of at least one of the light emitter 100 and the refractor 200. This ensures a sufficient light travel path from the light emitter 100, thereby enhancing the luminance uniformity and improving the quality of the light emitting device. Furthermore, the light transmittance of the optical component 300 may differ from that of the refractor 200. For instance, the light transmittance of the optical component 300 may be lower than that of the refractor 200. This may increase the amount of light extracted through the refractor 200, thereby improving the luminance. In this case, the difference in the transmittance between the optical component 300 and the refractor 200 may be 10% or more, enabling easier adjustment of the light travel path

The circuit board 20 may have an electrical circuit arranged thereon. The plurality of light emitting devices 10 may be arranged on the circuit board 20 to be connected to the electrical circuit. The electrical circuit of the circuit board 20 may supply electricity to the plurality of light emitters 100 of each of the plurality of light emitting devices 10. For example, the circuit board 20 may be a printed circuit board (PCB) on which the electrical circuit is printed. In addition, the circuit board 20 may be a thin-film transistor (TFT) backplane, in which a transistor circuit that controls a gate voltage to move electrons or holes from a source to a drain through an active layer and controls current flow is formed on a film-shaped thin film.

The cover 30 can support the circuit board 20 and protect the circuit board 20 and components from the external environment. In addition, the cover 30 may include a high-density material with a high thermal conductivity, thereby enhancing the reliability of the display device 1. The cover 30 can protect the light emitting device 10, the circuit board 20, and the optical sheet 40 from the external environment, and may have a higher hardness than the adjacent optical sheet 40.

The optical sheet 40 may be disposed on top of the circuit board 20 to diffuse and adjust light generated from the plurality of light emitting devices 10. The optical sheet 40 may include at least one of a diffusion sheet, a polarizing sheet, or a color conversion sheet. The optical sheet 40 may additionally include a diffusion sheet for light diffusion, a prism sheet for increasing light efficiency, etc. Hereinafter, with reference to FIG. 5, a light emitting device 10 and a display device 1 including the same according to an embodiment of the disclosed technology will be described.

In describing the second embodiment, the explanation will focus on the differences compared to the aforementioned embodiment, particularly in that at least one of the plurality of refractors 200 does not collect light.

The plurality of refractors 200 may not be disposed in a region directly above the third light emitter 130. For example, each of the plurality of refractors 200 may be arranged only in a region directly above the first light emitter 110 and the second light emitter 120. That is, the refractor 200 having a curvature may not be disposed in a region of the third light emitter. In addition, the difference in beam angle of the light emitter 100 depending on the presence or absence of the refractor 200 may be smallest for the third light emitter 130, and since the third angle, which is the difference in beam angle depending on the presence or absence of the refractor for the third light emitter 130, may be smaller than the first angle and the second angle, the light from the third light emitter 130 may be efficiently emitted to the outside even when the light is not collected by the refractor 200 above the third light emitter 130. In this case, the beam angle of the third light emitter 130 may be smaller than those of the first light emitter 110 and the second light emitter 120. In addition, since the refractor 200 is not disposed above the third light emitter 130 having the smallest beam angle, the light emission profile of the third light emitter 130 may be improved, thereby increasing the luminance uniformity and enhancing the quality of the light emitting device 10. In this case, a region of the optical component 300 disposed above the third light emitter 130 may have surface roughness. For example, the region of the optical component 300 disposed above the third light emitter 130 may include irregularities, grooves, or the like. This may improve the light extraction efficiency of the third light emitter 130.

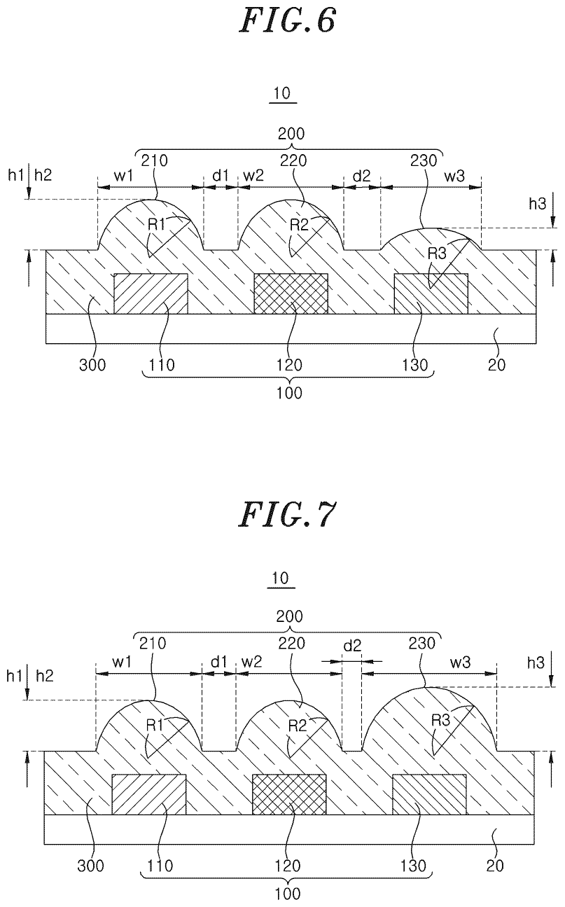

Hereinafter, with reference to FIG. 6, a light emitting device 10 and a display device 1 including the same according to an embodiment of the disclosed technology will be described.

In describing the third embodiment, there is a difference from the above-described embodiments in that the radius of curvature R1 of the first refractor 210 and the radius of curvature R2 of the second refractor 220 are the same, but may be smaller than the radius of curvature R3 of the third refractor 230, and this difference will be mainly described.

The curvature of the first refractor 210 and the curvature of the second refractor 220 may be formed to be the same. The height h1 of the first refractor 210 and the height h2 of the second refractor 220 may be formed to be the same. In addition, the width w1 of the bottom surface of the first refractor 210 and the width w2 of the bottom surface of the second refractor 220 may be formed to be the same.

The curvature of the third refractor 230 may be smaller than the curvatures of the first refractor 210 and the second refractor 220, which allows the path of light emitted from the third light emitter 130 to be bent less. The radius of curvature R3 of the third refractor 230 may be larger than the radius of curvature R1 of the first refractor 210 and the radius of curvature R2 of the second refractor 220. In addition, the center of the radius of curvature R3 of the third refractor 230 may be disposed lower than the center of the radius of curvature R1 of the first refractor 210 and the center of the radius of curvature R2 of the second refractor 220, which allows the design of the third refractor 230 having a large radius of curvature without encroaching on the areas of the first refractor 210 and the second refractor 220. Further, the width w3 of the bottom surface of the third refractor 230 may be formed longer than the width w1 of the lower surface of the first refractor 210 and the width w2 of the lower surface of the second refractor 220.

In addition, the separation distance d1 between the first refractor 210 and the second refractor 220 may be substantially equal to the separation distance d2 between the second refractor 220 and the third refractor 230, thereby ensuring equal spacing in the pixel region and improving the light uniformity. In this case, the difference between the separation distance d1 and the separation distance d2 may be less than 10%.

Hereinafter, with reference to FIG. 7, a light emitting device 10 and a display device 1 including the same according to an embodiment of the disclosed technology will be described.

In describing the fourth embodiment, there is a difference from the above-described embodiments in that the height h3 of the third refractor 230 may be greater than the height h1 of the first refractor 210 and the height h2 of the second refractor 220, and this difference will be mainly described.

The curvature of the first refractor 210 and the curvature of the second refractor 220 may be formed to be the same. The height h1 of the first refractor 210 and the height h2 of the second refractor 220 may be formed to be the same. In addition, the width w1 of the bottom surface of the first refractor 210 and the width w2 of the bottom surface of the second refractor 220 may be formed to be the same. In this case, the first light emitter 110 and the second light emitter 120 may have similar beam angles. Further, the beam angles of the light emitted from the first refractor 210 and the second refractor 220 may be similar. Furthermore, the first angle, which is the difference in beam angle between the first refractor 210 and the first light emitter 110, and the second angle, which is the difference in beam angle between the second refractor 220 and the second light emitter 120, may be similar to each other.

The curvature of the third refractor 230 may be smaller than the curvatures of the first refractor 210 and the second refractor 220. The radius of curvature R3 of the third refractor 230 may be larger than the radius of curvature R1 of the first refractor 210 and the radius of curvature R2 of the second refractor 220, so that the difference in beam angle between the third refractor 230 and the third light emitter 130 may form the third angle. The third angle may be smaller than the first angle, which is the difference in beam angle between the first refractor 210 and the first light emitter 110, and the second angle, which is the difference in beam angle between the second refractor 220 and the second light emitter 120. In addition, the center of the radius of curvature R3 of the third refractor 230 may be disposed at a height similar to the center of the radius of curvature R1 of the first refractor 210 and the center of the radius of curvature R2 of the second refractor 220, and may be disposed at the same height as or above the positions of the plurality of light emitters 100, thereby increasing the light extraction efficiency. Further, the width w3 of the bottom surface of the third refractor 230 may be formed longer than the width w1 of the bottom surface of the first refractor 210 and the width w2 of the bottom surface of the second refractor 220, thereby increasing the light emission area.

In addition, the separation distance d1 between the first refractor 210 and the second refractor 220 may be formed differently from the separation distance d2 between the second refractor 220 and the third refractor 230. For example, the separation distance d1 between the first refractor 210 and the second refractor 220 may be larger than the separation distance d2 between the second refractor 220 and the third refractor 230, so that the optical interference between the first refractor 210 and the second refractor 220 having the same beam angle may be reduced, compared to the optical interference that may occur with the third refractor 230 having a different beam angle.

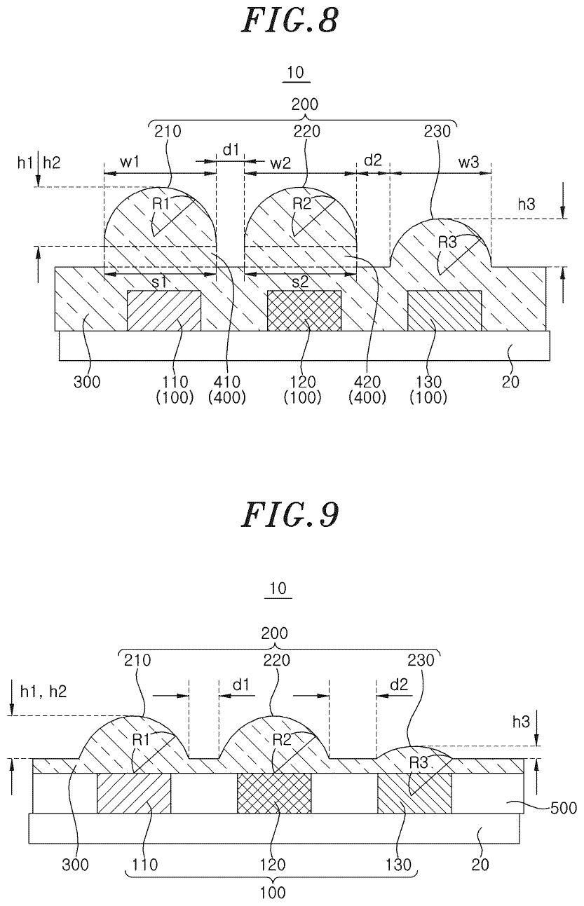

Hereinafter, with reference to FIG. 8, a light emitting device 10 and a display device 1 including the same according to an embodiment of the disclosed technology will be described.

In describing the fifth embodiment, there is a difference from the above-described embodiments in that a plurality of spacers 400 may be additionally included, and this difference will be mainly described.

The plurality of spacers 400 may be arranged between the plurality of refractors 200 and the optical component 300 to allow light to pass through. The plurality of spacers 400 may be formed integrally with the plurality of refractors 200 and the optical component 300. Such spacers 400 may reduce the delamination between the refractors 200 and the optical component 300, thereby improving the structural reliability. For example, the plurality of spacers 400, the plurality of refractors 200, and the optical component 300 may be formed of the same material, thereby reducing the number of interface layers and improving the structural stability. The plurality of spacers 400 may include a first spacer 410 and a second spacer 420.

The first spacer 410 may be disposed between the first refractor 210 and the first light emitter 110 to refract light from the first light emitter 110. The width s1 of the first spacer 410 may be the same as the width w1 of the bottom surface of the first refractor 210. The center of the radius of curvature R1 of the first refractor 210 may be disposed on or above one surface of the first spacer 410, thereby increasing the light refraction path and efficiently narrowing the emission angle.

The second spacer 420 is disposed between the second refractor 220 and the second light emitter 120 to refract light from the second light emitter 120. The width s2 of the second spacer 420 may be the same as the width w2 of the bottom surface of the second refractor 220. The center of the radius of curvature R2 of the second refractor 220 may be disposed on or above one surface of the second spacer 420, thereby increasing the light refraction path and efficiently narrowing the emission angle.

A separation distance d1 between the first spacer 410 and the second spacer 420 may be substantially equal to a separation distance d2 between the second spacer 420 and the third refractor 230, which allows the pixel spacing to appear uniform when viewed from the top. In this case, the difference between the separation distance d1 and the separation distance d2 may be less than 10%.

Hereinafter, with reference to FIGS. 9 to 11, a light emitting device 10 and a display device 1 including the same according to an embodiment of the disclosed technology will be described.

In describing the sixth embodiment, there is a difference from the above-described embodiments in that a light blocker 500 may be further included, and this difference will be mainly described.

The light blocker 500 may block or reflect light. The light blocker 500 may include fine particles such as carbon, titanium dioxide (TiO₂), barium sulfate (BaSO₄), silica, Zirconium dioxide (ZrO₂), alumina (Al₂O₃), Carbon black, Iron oxide (Fe₂O₃), NiO, CoO, Nd₂O₃, Sm₂O₃ to efficiently block light. In addition, the light blocker 500 may include pigments such as carbon black to enhance light absorption. The light blocker 500 may be disposed between the plurality of light emitters 100 and on an outer side of the plurality of light emitters 100. The height of the light blocker 500 may be higher than the height of the plurality of light emitters 100, thereby reducing the optical interference between the plurality of light emitters to realize clear pixel separation and improved color definition.

Referring to FIG. 9, as a first example, the light blocker 500 may be arranged to be in contact with at least one region of the plurality of light emitters 100, and may absorb or reflect light in at least that region. In this case, the optical component 300 may not be included. When the optical component 300 is not included, the light blocker 500 may be arranged between the plurality of refractors 200 such that the plurality of refractors 200 are spaced apart from each other. When the optical component 300 is included, the optical component 300 may be disposed on an upper surface of the light blocker 500, which lengthens the moisture penetration path and delays reliability degradation due to moisture. In addition, the height of the optical component 300 may be smaller than the height of the light blocker 500, which reduces the diffraction of light and decreases light emission in unintended regions.

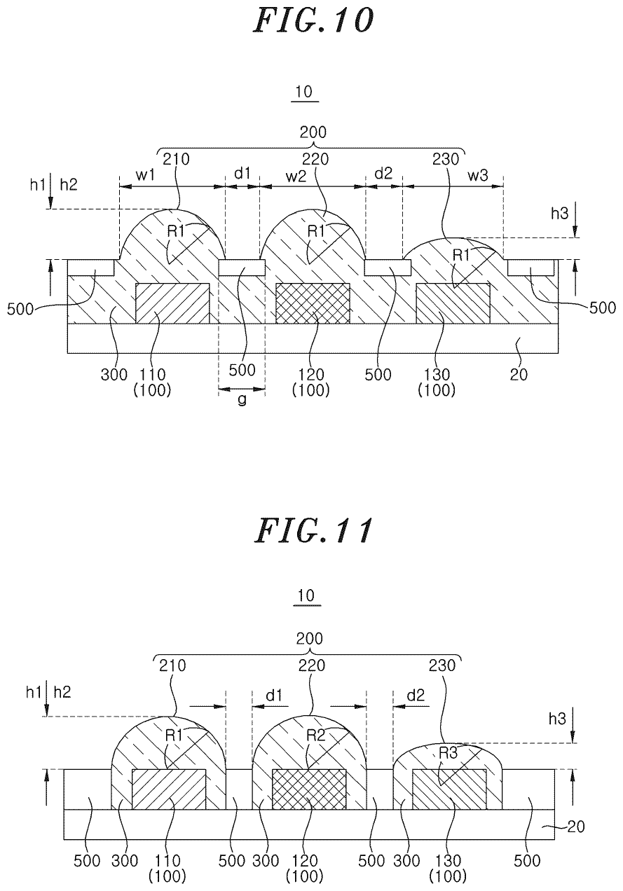

Referring to FIG. 10, as a second example, the light blocker 500 may be disposed on the upper surface of the optical component 300. In addition, the light blocker 500 may be disposed between the plurality of refractors 200, which minimizes the area that absorbs light and improves light extraction efficiency. The upper surface of the refractor 200 may be positioned above the upper surface of the light blocker 500. This configuration may efficiently increase contrast while minimizing the interference in the light travel path. Additionally, the height of the light blocker 500 may be lower than the maximum height of the refractor 200. For example, the height of the light blocker 500 may be lower than the height of the first refractor 210. Furthermore, the height of the light blocker 500 may be lower than the minimum height of the refractor 200; that is, it may be lower than the height of the third refractor 230. This allows for contrast improvement with a minimal impact on the light extraction direction. By increasing the light extraction efficiency, the optical interference may be effectively reduced.

The cross-sectional width g of the light blocker 500 may be greater than the separation distances between the refractors 200. For example, the cross-sectional width g of the light blocker 500 may be greater than the separation distance d1 between the first refractor 210 and the second refractor 220. The cross-sectional width g of the light blocker 500 may be greater than the separation distance d2 between the second refractor 220 and the third refractor 230. This enables the effective blocking of light. Conversely, the cross-sectional width g of the light blocker 500 may be smaller than the widths of the refractors 200. That is, the cross-sectional width g of the light blocker 500 may be smaller than the bottom widths w1, w2, and w3 of the first refractor 210, the second refractor 220, and the third refractor 230, respectively. This increases the light extraction efficiency and enhances the luminance by reducing the interference in the light travel path of the refractors 200.

Referring to FIG. 11, as a third example, the optical blocker 500 may be disposed between a plurality of optical components 300 and on the outside of the plurality of optical components 300. For example, the optical blocker 500 may be disposed to be in contact with at least one side region of the plurality of optical components 300. In this case, the plurality of optical components 300 may be spaced apart from each other by the optical blocker 500, so that the optical interference between the plurality of light emitters 100 may be reduced, thereby realizing an improved color definition and high contrast.

The width of the light blocker 500 disposed between the plurality of optical components 300 may be the same as a distance d1 or d2 between the plurality of optical components 300. This allows the interference in the light travel path to be reduced.

Alternatively, the width of the light blocker 500 disposed between the plurality of optical components 300 may be less than the distance d1 or d2 between the plurality of optical components 300. For example, since the light blocker 500 may be arranged to be spaced apart from the plurality of light emitters 100, side-emitted light may be released through a region of the optical component 300, thereby improving the light extraction efficiency.

Alternatively, the width of the light blocker 500 disposed between the plurality of optical components 300 may be greater than the distance d1 or d2 between the plurality of optical components 300. In addition, since the plurality of optical components 300 may be joined to a side surface of at least one of the light emitters 100, thereby efficiently blocking the side-emitted light and enabling the implementation of a light emitting device with high directivity.

In this case, the height of the plurality of light blockers 500 may be greater than the height of the light emitters 100. This may reduce optical interference between the multiple light emitters 100, thereby improving the color sharpness. Additionally, the height of the light blocker 500 may be lower than the height from the upper surface of the circuit board 20 to the upper surface of the optical component 200. This prevents interference with the light travel path toward the optical component 200, thereby enhancing the light extraction efficiency. Conversely, the height from the upper surface of the circuit board 20 to the upper end of the light blocker 500 may be greater than the height from the upper surface of the light emitter 100 to the highest upper surface of the optical component 200. This allows for improved contrast.

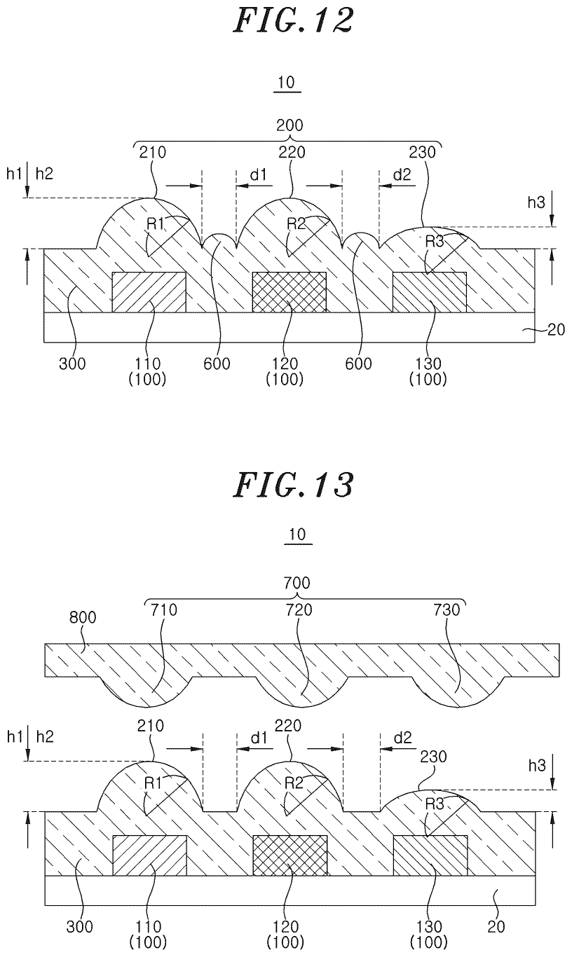

Hereinafter, with reference to FIG. 12, a light emitting device 10 and a display device 1 including the same according to an embodiment of the disclosed technology will be described.

In describing the seventh embodiment, there is a difference from the above-described embodiments in that an auxiliary refractor 600 may be further included between the plurality of refractors 200, and this difference will be mainly described.

The auxiliary refractor 600 may be disposed one or more of the following: between the first refractor 210 and the second refractor 200, and between the second refractor 220 and the third refractor 230. The height of the auxiliary refractor 600 may be smaller than the respective heights of the first refractor 210, the second refractor 200, and the third refractor 230. Since the auxiliary refractor 600 may totally reflect light traveling between the plurality of refractors 200, the light from adjacent light emitters 100 may be prevented from mixing or interfering with each other, and the color distinction between the light emitters 100 can be made clearer. The upper surface of the auxiliary refractor 600 may be spaced apart from the upper surfaces of the first refractor 210, the second refractor 220, and the third refractor 230. This may reduce optical interference between the dimming zones. The radius of curvature of the auxiliary refractor 600 may be smaller than the radii of curvature R1, R2, and R3 of the first refractor 210, the second refractor 220, and the third refractor 230, respectively. This reduces the amount of light directed toward the auxiliary refractor 600, thereby minimizing the interference between dimming zones. The radius of curvature of the auxiliary refractor 600 may also be smaller than the separation distances d1 and d2.

Hereinafter, with reference to FIG. 13, a light emitting device 10 and a display device 1 including the same according to an embodiment of the disclosed technology will be described.

In describing the eighth embodiment, the plurality of refractors 200 described above will be referred to as a plurality of lower refractors 200, and the optical component 300 will be referred to as a lower optical component 300. In addition, in describing the eighth embodiment, there is a difference from the above-described embodiments in that a plurality of upper refractors 700 and an upper optical component 800 may be further included, and this difference will be mainly described.

The plurality of upper refractors 700 may be arranged above the plurality of lower refractors 200 to collect the light transmitted through the plurality of lower refractors 200. The plurality of upper refractors 700 may be formed to be convex downward. Further, the plurality of upper refractors 700 may be arranged to be spaced apart upward from the plurality of lower refractors 200 by a predetermined distance to adjust the optical focal length, but the disclosed technology is not limited thereto. For example, the plurality of upper refractors 700 and the plurality of lower refractors 200 may be connected. In addition, the curvature of one of the plurality of lower refractors 200 and the plurality of upper refractors 700 may be formed differently from the curvature of the other one of the plurality of lower refractors 200 and the plurality of upper refractors 700.

The plurality of upper refractors 700 may include a first upper refractor 710, a second upper refractor 720, and a third upper refractor 730.

The first upper refractor 710 may be disposed above the first lower refractor 210 to collect light transmitted through the first lower refractor 210. The first upper refractor 710 may be formed to be convex toward the first lower refractor 210. In this case, the distance between the first upper refractor 710 and the first lower refractor 210 may be shorter than the distance between the lower optical component 300 and the upper optical component 800, which enables efficient light collection.

The second upper refractor 720 may be disposed above the second lower refractor 220 to collect light transmitted through the second lower refractor 220. The second upper refractor 720 may be formed to be convex toward the second lower refractor 220. In this case, the distance between the second upper refractor 720 and the second lower refractor 220 may be shorter than the distance between the lower optical component 300 and the upper optical component 800, which enables efficient light collection.

The third upper refractor 730 may be disposed above the third lower refractor 230 to collect light transmitted through the third lower refractor 230. The third upper refractor 730 may be formed to be convex toward the third lower refractor 230. In this case, the distance between the third upper refractor 730 and the third lower refractor 230 may be shorter than the distance between the lower optical component 300 and the upper optical component 800, which enables efficient light collection.

The curvatures of the first upper refractor 710, the second upper refractor 720, and the third upper refractor 730 may be formed identically. When light is transmitted through the first upper refractor 710, the second upper refractor 720, and the third upper refractor 730, the light may be refracted while maintaining the deviation between the beam angles adjusted by the lower refractors 200, so that the deviation between the final emission angles of the light transmitted through the plurality of upper refractors 700 may be maintained constant. For example, in the lower refractors 200, the difference in beam angles between the first light emitter 110, the second light emitter 120, and the third light emitter 130 is improved to make the beam angles thereof similar, and in the upper refractors 700, the deviation between the improved beam angles may be maintained. The curvature of any one of the first upper refractor 710, the second upper refractor 720, and the third upper refractor 730 may be formed differently from the curvature of another one of the first upper refractor 710, the second upper refractor 720, and the third upper refractor 730, which allows light to be adjusted to have different projection areas for each pixel in the final stage as needed. For example, in the light emitting device applied to an automobile headlamp, the light emitted from the first light emitter 110 may implement a low beam with a wide projection area, and the light emitted from the third light emitter 130 may implement a high beam with a narrow and distant projection area.

Further, the first upper refractor 710, the second upper refractor 720, and the third upper refractor 730 may be formed to have the same height, and when light is transmitted therethrough, the light may be refracted while maintaining the deviation between the beam angles adjusted by the lower refractors 200, so that the deviation between the final emission angles may be maintained constant. However, the disclosed technology is not limited to the above. For example, in the lower refractor 200, the difference in beam angles between the first light emitter 110, the second light emitter 120, and the third light emitter 130 is improved to make the beam angles thereof similar, and in the upper refractor 700, the deviation between the improved beam angles may be maintained. In addition, the height of any one of the first upper refractor 710, the second upper refractor 720, and the third upper refractor 730 may be formed differently from the height of another one of the first upper refractor 710, the second upper refractor 720, and the third upper refractor 730, which allows light to be guided to have different projection areas. For example, in the light emitting device applied to an automobile headlamp, the light emitted from the first light emitter 110 may implement a low beam with a wide projection area, and the light emitted from the third light emitter 130 may implement a high beam with a narrow and distant projection area.

In addition, the first upper refractor 710 may be formed identical to the first lower refractor 210, and the second upper refractor 720 may be formed identical to the second lower refractor 220, and the third upper refractor 730 may be formed identical to the third lower refractor 230.

The upper optical component 800 may be disposed on the upper surfaces of the plurality of upper refractors 700 to transmit light passing through the plurality of upper refractors 700. The upper optical component 800 may be formed integrally with the plurality of upper refractors 700. For example, the upper optical component 800 may be formed of the same material as the plurality of upper refractors 700. Therefore, it is possible to prevent delamination between the plurality of upper refractors 700 and the upper optical component 800. However, the disclosed technology is not necessarily limited to the above, and depending on the light profile to be implemented, the plurality of upper refractors 700 and the upper optical component 800 may be formed of different materials.

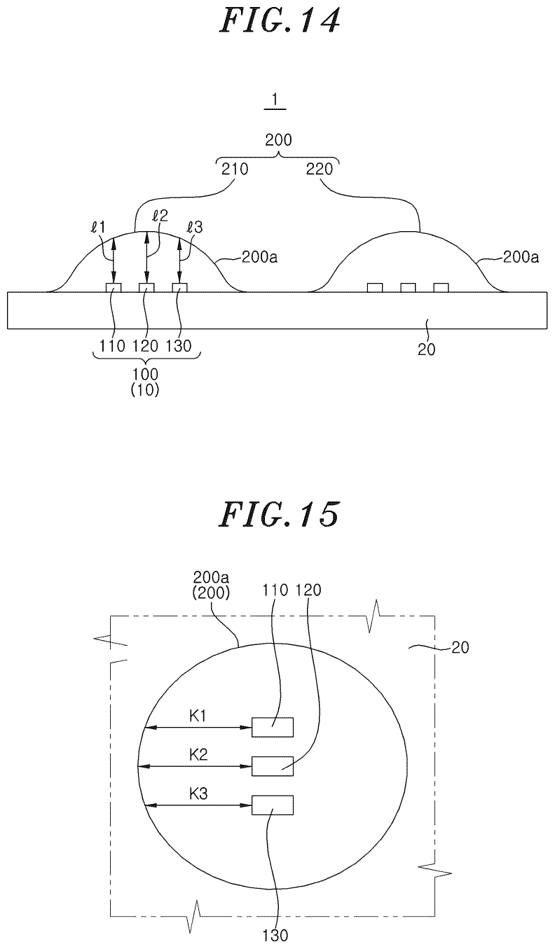

Referring to FIGS. 14 to 16, a light emitting device 10 and a display device 1 including the same according to an embodiment of the disclosed technology will be described.

In describing the ninth embodiment, the explanation will focus on the difference that a plurality of light emitters 100 may be disposed in a lower portion of a single refractor 200.

Referring to FIG. 14, a plurality of light emitters 100 may be disposed in a lower portion of a single refractor 200. The plurality of light emitters 100 may share one refractor 200. For example, the plurality of light emitters 100 may be disposed in a lower portion of the first refractor 210, and the plurality of light emitters 100 may be disposed in a lower portion of the second refractor 220. The separation distance between the plurality of light emitters 100 that share a refractor 200 may be smaller than the separation distance between light emitters 100 that do not share a refractor 200. For example, the separation distance between the plurality of light emitters 100 disposed in the lower portion of the first refractor 210 may be smaller than the separation distance between the light emitter 100 disposed in the lower portion of the first refractor 210 and the light emitter 100 disposed in the lower portion of the second refractor 220. The separation distance between light emitters 100 that do not share a refractor 200 may be 3 to 12 times greater than the separation distance between light emitters 100 that do share a refractor 200. This may minimize the optical interference between light emitters 100 that do not share a refractor 200, thereby improving the contrast. In this case, the plurality of light emitters 100 that share a refractor 200 may emit different wavelengths. As a result, improvements in color sharpness and color reproduction may be achieved.

Further, each of the plurality of light emitters 100 that share the refractor 200 may have a different vertical distance from the light emitting surface of the refractor 200. The plurality of light emitters 100 sharing the refractor 200 may include a first light emitter 110, a second light emitter 120, and a third light emitter 130. For example, the light emitting surface 200a may be formed as a curved surface, and the vertical separation distances between the light emitters and the light emitting surface 200a-namely, a first vertical separation distance 11 between the first light emitter 110 and the light emitting surface 200a, a second vertical separation distance 12 between the second light emitter 120 and the light emitting surface 200a, and a third vertical separation distance 13 between the third light emitter 130 and the light emitting surface 200a—may all be different from one another. Here, the vertical direction may refer to a direction perpendicular to the surface of the circuit board 20. The second vertical separation distance 12 may be greater than the first vertical separation distance 11 and the third vertical separation distance 13. As a result, the light extraction efficiency of the second light emitter 120 may be improved, leading to enhanced color reproduction. The first vertical separation distance 11 may be 2% to 9% shorter than the second vertical separation distance 12. Further, the third vertical separation distance 13 may be 3% to 8% shorter than the second vertical separation distance 12. The second light emitter 120 may have a peak wavelength shorter than that of the first light emitter 110 or the third light emitter 130.

Further referring to FIG. 15, in the horizontal direction, the horizontal separation distances between the sides of the plurality of light emitters 100 and the light emitting surface of the refractor 200 may be formed differently. The horizontal direction may refer to a direction extending along the surface of the circuit board 20 and perpendicular to the direction in which the plurality of light emitters 100 are arranged. For example, since the light emitting surface 200a is formed as a curved surface, a first horizontal separation distance k1 between the first light emitter 110 and the light emitting surface 200a, a second horizontal separation distance k2 between the second light emitter 120 and the light emitting surface 200a, and a third horizontal separation distance k3 between the third light emitter 130 and the light emitting surface 200a may all differ from one another. The second horizontal separation distance k2 may be greater than the first horizontal separation distance k1 and the third horizontal separation distance k3. For example, the second horizontal separation distance k2 may be 3% to 12% longer than the first horizontal separation distance k1 or the third horizontal separation distance k3. As a result, the light extraction efficiency of the second light emitter 120 may be improved, thereby enhancing color sharpness and color reproduction.

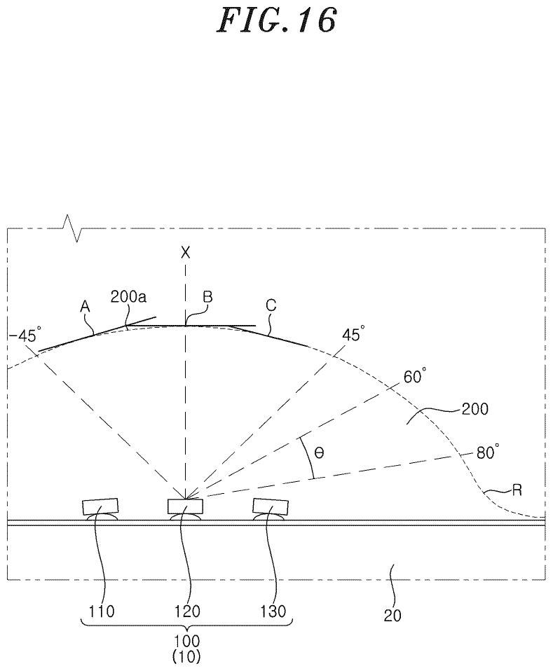

Further referring to FIG. 16, the curvature of the refractor 200 may vary by region. The curvature of the refractor 200 may be greatest in a side region R that is disposed lower than the height of the light emitter 100. This allows side-emitted light to be redirected toward the front, thereby increasing the luminance. In addition, the curvature of the refractor 200 may be smallest in a central region disposed directly above the light emitter 100. This may improve the vertical light extraction efficiency of the light emitter 100, thereby increasing the luminance. The radius of curvature of the refractor 200 may be largest in the central region. For example, the radius of curvature of the refractor 200 may be largest in the region directly above the second light emitter 120 among the plurality of light emitters 100. As a result, the light extraction efficiency of the second light emitter 120, which may have a relatively low luminous intensity, may be improved, thereby enhancing the light uniformity.

Meanwhile, a virtual line passing through the center of the second light emitter 120 in the vertical direction is referred to as a device center line X. Among the regions of the refractor 200, the curvature of a region disposed within a predetermined angular range θ based on the device center line X may be greater than the curvature of the central region of the refractor 200. Here, the angular range θ may be equal to or greater than 60° and equal to or less than 80°. This allows light within a viewing angle equal to or greater than 60° and equal to or less than 80° to be refracted, thereby increasing the luminance of the light emitting device 1.

In addition, among the regions of the refractor 200, the regions respectively overlapping the top surfaces of the first light emitter 110, the second light emitter 120, and the third light emitter 130 may have different curvatures. The region of the refractor 200 that overlaps the top surface of the first light emitter 110 is referred to as a first refraction region A, the region overlapping the top surface of the second light emitter 120 is referred to as a second refraction region B, and the region overlapping the top surface of the third light emitter 130 is referred to as a third refraction region C. The curvature of the first refraction region A and the third refraction region C may be greater than the curvature of the second refraction region B. For example, the refractor 200 may be formed such that the tangents of the first refraction region A and the third refraction region C are inclined at a greater angle with respect to the surface of the circuit board 20 than the tangent of the second refraction region B. As a result, the viewing angle of the first light emitter 110 may be reduced. For example, the viewing angle of the first light emitter 110 with the refractor 200 removed and the viewing angle of the first light emitter 110 formed by the refractor 200 may differ by a predetermined first angle. Likewise, the viewing angle of the second light emitter 120 with the refractor 200 removed and the viewing angle of the second light emitter 120 formed by the refractor 200 may differ by a predetermined second angle. The first angle may be greater than the second angle. Additionally, the viewing angle of the third light emitter 130 with the refractor 200 removed and the viewing angle of the third light emitter 130 formed by the refractor 200 may differ by a predetermined third angle. The third angle may be greater than the second angle. At this time, the first refraction region A, the second refraction region B, and the third refraction region C may be arranged within an angular range of −45° to 45° centered on the device centerline X. This may overcome the differences in the viewing angles among the light emitters, enabling clearer color reproduction.

At least some of the top surfaces of the first light emitter 110, the second light emitter 120, and the third light emitter 130 may be arranged tilted with respect to the circuit board 20. Each of the plurality of light emitters 100 may be tilted to match the curved surface of the light emitting surface 200a of the refractor 200. For example, the top surface of the first light emitter 110 may be tilted to the left, following the direction in which the tangent of the first curvature region A is inclined. Further, the top surface of the third light emitter 130 may be tilted to the right, following the direction in which the tangent of the third curvature region C is inclined. This allows for the efficient adjustment of the emission angle by controlling the angle formed with the top surface of the refractor 200.

The examples of the disclosed technology have been described above as specific embodiments, but these are only examples, and the disclosed technology is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the disclosed technology. In addition, those skilled in the art can easily change or modify the disclosed embodiments based on the present specification, and it is clear that such changes or modifications also belong to the scope of the disclosed technology.

### EXPLANATION OF SYMBOLS

| | |
|---|---|
| 1: display device | 20: display substrate |
| 30: cover | 40: optical sheet |
| 10: light emitting device | 100: light emitter |
| 110: first light emitter | 120: second light emitter |
| 130: third light emitter | 200: refractor |
| 210: first refractor | 220: second refractor |
| 230: third refractor | 300: optical component |
| 400: spacer | 410: first spacer |
| 420: second spacer | 500: light blocker |
| 600: auxiliary refractor | 700: upper refractor |
| 710: first upper refractor | 720: second upper refractor |
| 730: third upper refractor | 800: upper optical component |

1. A light emitting device, comprising:
a substrate;
a plurality of light emitters including a first light emitting diode and a second light emitting diode disposed on the substrate; and
a plurality of refractors disposed on top surfaces of at least one of the plurality of light emitters,
wherein a curvature of a first region of the plurality of refractors disposed on the first light emitting diode is different from a curvature of a second region disposed on the second light emitting diode.

2. The light emitting device of claim 1, further comprising:
an optical component on which the plurality of refractors are arranged, which covers the plurality of light emitters, and is configured to pass light generated from the plurality of light emitters.

3. The light emitting device of claim 1, wherein the plurality of light emitters includes:
the first light emitter, which is configured to generate a first light having a first peak wavelength; and
a second light emitter, which is configured to generate a second light having a second peak wavelength different from the first peak wavelength, and
wherein the plurality of refractors includes:
a first refractor disposed above the first light emitter and formed to be convex upward to collect light from the first light emitter; and
a second refractor disposed above the second light emitter and formed to be convex upward to collect light from the second light emitter.

4. The light emitting device of claim 3, wherein a radius of curvature of the first refractor is smaller than a radius of curvature of the second refractor.

5. The light emitting device of claim 4, wherein a center of the radius of curvature of the first refractor is disposed above a center of the radius of curvature of the second refractor.

6. The light emitting device of claim 3, wherein the plurality of light emitters further includes a third light emitter configured to generate a third light having a second peak wavelength different from that of the first light emitter and the second light emitter, and
wherein the plurality of refractors are not disposed in a region directly above the third light emitter.

7. The light emitting device of claim 3, wherein the plurality of light emitters further includes a third light emitter configured to generate light of a different color from those of the first light emitter and the second light emitter, and
the plurality of refractors further includes a third refractor disposed above the third light emitter and formed to be convex upward to collect light from the third light emitter.

8. The light emitting device of claim 7, wherein a radius of curvature of the third refractor is greater than a radius of curvature of the first refractor and a radius of curvature of the second refractor, and
the radius of curvature of the second refractor is greater than the radius of curvature of the first refractor.

9. The light emitting device of claim 8, wherein a center of the radius of curvature of the third refractor is disposed below a center of the radius of curvature of the first refractor and a center of the radius of curvature of the second refractor, and
the center of the radius of curvature of the second refractor is disposed below the center of the radius of curvature of the first refractor.

10. The light emitting device of claim 7, wherein a radius of curvature of the first refractor and a radius of curvature of the second refractor are identical, and
a radius of curvature of the third refractor is greater than the radius of curvature of the first refractor and the radius of curvature of the second refractor.

11. The light emitting device of claim 10, wherein a center of the radius of curvature of the third refractor is disposed below a center of the radius of curvature of the first refractor and a center of the radius of curvature of the second refractor.

12. The light emitting device of claim 11, wherein a height of the third refractor is smaller than a height of the first refractor and a height of the second refractor.

13. The light emitting device of claim 11, further comprising:
a first spacer disposed between the first refractor and the first light emitter, and configured to transmit the first light, and
a second spacer disposed between the second refractor and the second light emitter, and configured to transmit the second light,
wherein the center of the radius of curvature of the first refractor is disposed above the first spacer, and
the center of the radius of curvature of the second refractor is disposed above the second spacer.

14. The light emitting device of claim 11, wherein the first refractor, the second refractor, and the third refractor are arranged to be spaced from each other in a horizontal direction, and
a separation distance between the first refractor and the second refractor is identical to a separation distance between the second refractor and the third refractor.

15. The light emitting device of claim 10, wherein a center of the radius of curvature of the third refractor is disposed at a same level as or above a center of the radius of curvature of the first refractor and a center of the radius of curvature of the second refractor.

16. The light emitting device of claim 15, wherein a height of the third refractor is equal to or greater than a height of the first refractor and a height of the second refractor.

17. The light emitting device of claim 15, wherein the first refractor, the second refractor, and the third refractor are arranged to be spaced from each other in a horizontal direction, and
a separation distance between the first refractor and the second refractor is greater than a separation distance between the second refractor and the third refractor.

18. The light emitting device of claim 7, further comprising:
a light blocker configured to block light generated by the plurality of light emitters,
wherein the light blocker is disposed between the plurality of light emitters and on an outer side of the plurality of light emitters.

19. A light emitting device, comprising:
a plurality of light emitters configured to generate light;
a plurality of lower refractors arranged above the plurality of light emitters to collect light generated from at least some of the plurality of light emitters; and
a plurality of upper refractors arranged above the plurality of lower refractors, and configured to collect light transmitted through the plurality of lower refractors,
wherein a curvature of one of the plurality of lower refractors and the plurality of upper refractors is different from a curvature of another one of the plurality of lower refractors and the plurality of upper refractors.

20. A display device, comprising:
a light emitting device; and
a circuit board on which the light emitting device is arranged,
wherein the light emitting device includes
a plurality of light emitters configured to generate light; and
a plurality of refractors configured to collect light generated from at least some of the light emitters,
wherein a curvature of one of the plurality of refractors is different from a curvature of another of the plurality of refractors.
